(19) United States
(12) Patent Application Publication
(10) Pub. No.: US 2008/0107810 A1
(43) Pub. Date: May 8, 2008

(54) METHOD FOR FORMING ANTI-CORROSION AND ANTI-OXIDATION COATING LAYER ON HIGH-TEMPERATURE COMPONENTS OF GAS TURBINE FUEL ADDITIVE

(76) Inventors: Min Tae KIM, Yuseong-gu (KR); Sung Yong Chang, Yuseong-gu (KR); Jong Bum Won, Yuseong-gu (KR)

Correspondence Address: KENYON & KENYON LLP, ONE BROADWAY, NEW YORK, NY, 10004, US

(21) Appl. No.: 11/836,565

(22) Filed: Aug. 9, 2007

(30) Foreign Application Priority Data
Nov. 3, 2006 (KR) 10-2006-0108179

(51) Int. Cl. C23C 16/06

(52) U.S. Cl. 427/251; 427/250

(57) ABSTRACT

In a method for effectively depositing an anti-corrosion and anti-oxidation material, such as silicon dioxide, on high-temperature components of a gas turbine, including blades rotating at a high speed during the operation of the gas turbine, an organic compound including a metal ingredient, such as silicon, is added to a fuel for the gas turbine, such as LNG, diesel or kerosene, or the organic compound is sprayed into combustion air so that the organic compound can burn together with the fuel, in order to improve the durability of the high-temperature components. Silicon dioxide, produced by burning a silicon organic compound together with the fuel, is uniformly deposited on all the high-temperature components of the gas turbine, which are exposed to the combustion gas of a high temperature, thus forming an anti-corrosion and anti-oxidation coating layer of a thickness of several to several tens of μm on the high-temperature components during the operation of the gas turbine.

### CROSS-REFERENCE TO RELATED APPLICATIONS

The present application claims priority to Application No. 10-2006-0108179, filed in the Republic of Korea on Nov. 3, 2006, which is expressly incorporated herein in its entirety by reference thereto.

### FIELD OF THE INVENTION

The present invention relates to a method for effectively depositing an anti-corrosion and anti-oxidation material, such as silicon dioxide, on high-temperature components of a gas turbine, including blades rotating at a high speed during the operation of the gas turbine, by adding an organic compound including a metal ingredient, such as silicon, to a fuel, such as LNG, diesel or kerosene, or spraying the organic compound into combustion air so that the organic compound can burn together with the fuel, thus forming an oxide coating layer on the high-temperature components exposed to the combustion gas of a high temperature during the operation of the gas turbine for the purpose of improving the high temperature corrosion resistance and oxidation resistance of the high-temperature components of the gas turbine.

### BACKGROUND INFORMATION

In general, a turbine part of a gas turbine for a combined power-generating system is operated at a high temperature of 1,000° C. or more, and thus the turbine part may be severely deteriorated due to oxidation of the surfaces of components of the turbine and fatigue fracture accompanied by repeated start and stop of the turbine occurs frequently. High-temperature components of the gas turbine, which are operated in the above severe conditions, have a short life span of approximately 3 to 4 years, and in the case that these components are not used as a base but are used as a high-peak, the components have a more shortened life span and the gas turbine has a shortened repair cycle.

Under these circumstances, the coating of high-temperature components of a gas turbine, which are made of a nickel-based superalloy, with a proper protective layer for increasing thermal resistance, oxidation resistance, and corrosion resistance of the components has been researched and developed from a long time. For this reason, thermal barrier coating (TBC) with Yttria Stabilized Zirconia (YSZ, i.e., ZrO₂ including 8% by weight of Y₂O₃) has been put to practical use and applied to some components. Further, ceramic coating with silicon dioxide or alumina having excellent corrosion resistance and oxidation resistance has been applied to corresponding components using conventional techniques, i.e., a physical method, such as thermal spray, and chemical vapor deposition.

However, the above coating techniques are applied to a manufacturing step of the components of the gas turbine, and thus have certain disadvantages, such as need for separate process, equipment, and man power for coating the components, and prolongation of the manufacturing period of the components.

### SUMMARY

Example embodiments of the present invention provide a method for effectively depositing an anti-corrosion and anti-oxidation material, such as silicon dioxide, on high-temperature components of a gas turbine, including blades rotating at a high speed during the operation of the gas turbine, without separate process, equipment and man power, by adding an organic compound including a silicon ingredient to a fuel for the gas turbine, such as LNG, diesel or kerosene, or spraying the organic compound into combustion air so that the organic compound can burn together with the fuel.

Example embodiments of the present invention provide high-temperature components of a gas turbine, on which an oxide coating layer having a thickness of several to several tens of μm is formed by uniformly depositing silicon dioxide, produced by the combustion of an silicon organic compound together with a fuel, on all the high-temperature components of the gas turbine exposed to combustion gas of high-temperature, without a separate manufacturing process.

According to example embodiments of the present invention, a method is provided for effectively depositing silicon dioxide, produced by oxidizing silicon contained in an organic compound, on high-temperature components of a gas turbine during the operation of the gas turbine by adding the organic compound including a metal ingredient, such as silicon, to a fuel, such as LNG, diesel or kerosene, or spraying the organic compound into combustion air so that the organic compound can burn together with the fuel.

That is, in order to increase thermal resistance (high temperature corrosion resistance and oxidation resistance) of the high-temperature components of the gas turbine, for example, a combustion can, first-stage blades, first-stage nozzles, second-stage blades, and second-stage nozzles, which are operated at an ultra-high temperature of 800 to 1,500° C., a small amount of the organic compound including silicon is added to the fuel, such as LNG, diesel or kerosene, and burns together with the fuel, thus forming a silicon dioxide layer on the high-temperature components contacting combustion gas of high-temperature to a thickness of at least several μm during the operation of the gas turbine without a separate manufacturing process.

In order to coat high-temperature components of a gas turbine with a material having excellent corrosion resistance and oxidation resistance, such as silicon, by a conventional method, separate process, equipment and man power are required and the manufacturing period of the components is inevitably elongated. Further, unnecessary regions of the gas turbine may be coated, and necessary regions of the gas turbine may be inadequately coated.

In the case that LNG is used as the fuel of the gas turbine, it may be provided that a silicon organic compound evaporated at a relatively low temperature, i.e., tetraethyl orthosilicate (TEOS, C₈H₂₀O₄Si, boiling point=168° C.), is used as a fuel additive. At the vaporizing temperature of the silicon organic compound or more, the silicon organic compound is easily mixed with LNG, and thus provides the stable combustion.

On the other hand, in the case that diesel or kerosene is used as the fuel of the gas turbine, it may be provided that silicon oil having similar viscosity to that of diesel or kerosene is used. The silicon oil having similar viscosity to that of diesel or kerosene is easily diluted with diesel or kerosene, and thus provides the stable combustion.

In a power-generating large-sized gas turbine, air cooling holes are formed through first-stage blades. In this case, when the silicon organic compound is sprayed into air, the silicon organic compound flows through the air cooling holes and may cause harmful effects. Accordingly, the spray of the silicon organic compound into air is not preferable. Further, the amount of the silicon organic compound added to the fuel may be less than 3%, and, e.g., less than 1%, so as not to affect the stable combustion.

The silicon dioxide deposited on the high-temperature components of the gas turbine has a thickness of, e.g., 1 to 10 μm. In the case that the thickness of the silicon dioxide exceeds 10 μm, the silicon dioxide may be easily removed from a base metal or a thermal barrier coating layer due to internal stress.

In a method according to an example embodiment of the present invention, silicon oxide in a gas or fine solid state flows along the combustion gas of a high temperature, and contacts the high-temperature components, thus being effectively coated on proper regions.

According to an example embodiment of the present invention, a method for forming an anti-corrosion and anti-oxidation coating layer on high-temperature components of a gas turbine using a fuel additive includes: coating surfaces of the high-temperature components contacting combustion gas with a metal oxide having high thermal resistance during operation of the gas turbine by at least one of (a) adding a metal organic compound, including a metal ingredient, in one of (a) a gas and (b) a liquid state to a fuel of the gas turbine and (b) spraying the organic compound into combustion air so that the organic compound burns together with the fuel during the operation of the gas turbine to increase the thermal resistance of the high-temperature components.

The metal organic compound may include a silicon organic compound.

The high-temperature components of the gas turbine may include at least one of (a) a combustion can, (b) first-stage blades, (c) first-stage nozzles, (d) second-stage blades and (e) and second-stage nozzles.

The high-temperature components of the gas turbine may be coated in the coating step by thermal barrier coating (TBC) with Yttria Stabilized Zirconia (YSZ).

The fuel of the gas turbine may include at least one of (a) LNG, (b) diesel and (c) kerosene fuel.

An amount of the metal organic compound added may be in a range of 3% or less.

The metal oxide formed on the high-temperature components may include silicon dioxide.

The metal oxide formed on the high-temperature components may have a thickness of 1 to 10 μm.

The silicon organic compound may include tetraethyl orthosilicate (TEOS).

The silicon organic compound may include silicon oil.

The above and other aspects, features and advantages of the example embodiments of the present invention are described in more detail below with reference to the appended Figures.

### BRIEF DESCRIPTION OF THE DRAWINGS

FIG. 1A is a photograph of the external appearance of a micro gas turbine.

FIG. 1B is a photograph of a combustion gas outlet of the micro gas turbine.

FIG. 2A is a photograph of the exterior of a combustion chamber of the micro gas turbine.

FIG. 2B is a photograph of a rotary shaft connected to a turbine and an air compressor, passing through the combustion chamber, of the micro gas turbine.

FIG. 3 is a photograph showing turbine blades and the outlet, coated with silicon dioxide, of the gas turbine.

FIG. 4 is a photograph of the internal surface of a combustion can contacting a combustion gas in the combustion chamber.

FIG. 5 is a photograph of the turbine blades, on which a coating layer is formed.

FIG. 6A is a SEM image of the section of a coating layer formed on the turbine blades.

FIG. 6B is a component map of silicon in the coating layer of FIG. 6A.

FIG. 6C is a component map of oxygen in the coating layer of FIG. 6A.

FIG. 7 is a SEM image of the surface of the coating layer of FIG. 6A.

FIG. 8 is a SEM image of the section of the coating layer of FIG. 6A, from which a porous layer is removed.

### DETAILED DESCRIPTION

Example embodiments of the present invention are described in further detail with reference to the appended Figures.

### Example 1

### Combustion Test for Forming a Coating Layer

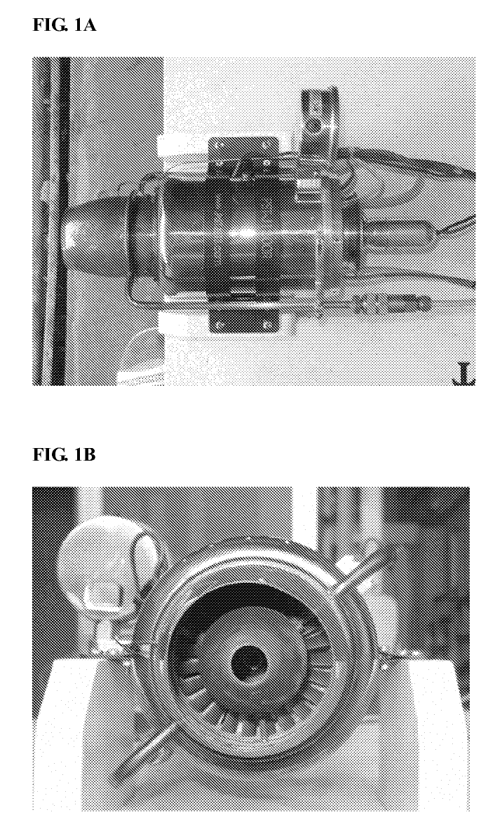

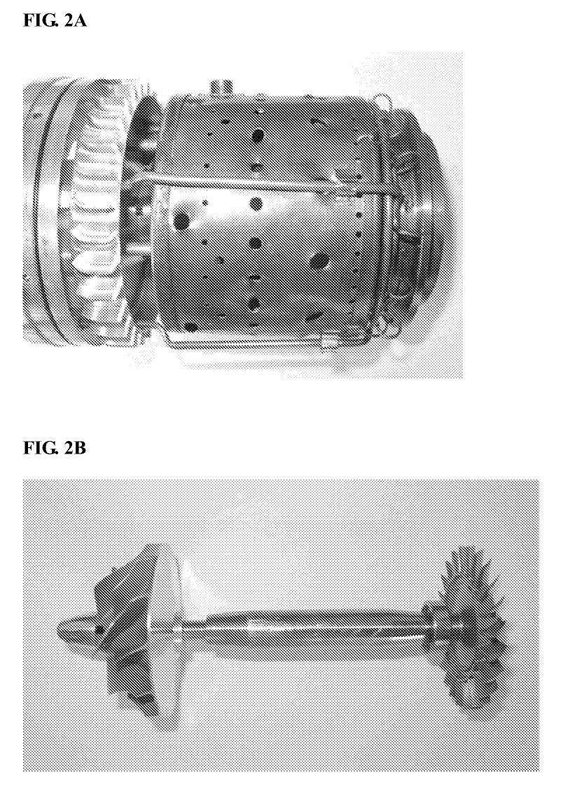

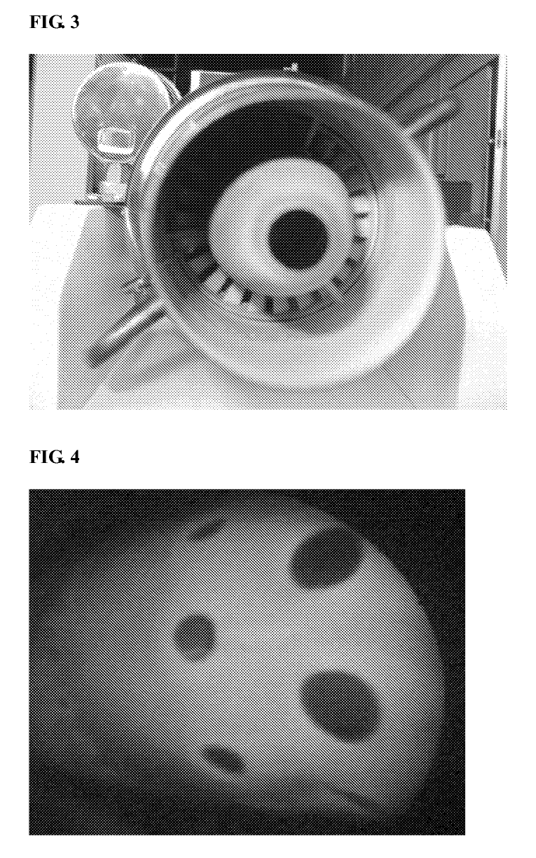

In this example, a micro gas turbine having a static thrust of 13 kgf at 135,000 rpm, which is loaded on a miniature airplane, as illustrated in FIGS. 1A and 1B, is used. Such a gas turbine is provided with a combustion chamber formed therein, as shown in FIG. 2A, and has a structure in which an air compressor (inhaler) and an integral turbine, passing through the combustion chamber, are connected by a single shaft, as illustrated in FIG. 2B. When the gas turbine is operated, butane gas may be used as a fuel, and a silicon organic compound, i.e., TEOS, may be sprayed in front of the air compressor, and thus flown into the combustion chamber together with air. After the operation of the gas turbine is started, the gas turbine is stably operated at 25,000 rpm, and TEOS sprayed together with air is combusted. Thereby, organic materials including carbon (C) are oxidized and thus produce carbon monoxide (CO), carbon dioxide (CO₂), and water (H₂O), and carbon monoxide (CO), carbon dioxide (CO₂), and water (H₂O) were discharged to the outside. Further, a silicon (Si) ingredient in TEOS is oxidized and thus produces silicon oxide (SiO_{X}, X=1-2), and silicon oxide is discharged to the outside together with white smoke or is uniformly coated on the turbine blades and the inside of an outlet, thus forming a white coating layer, as illustrated in FIG. 3. Moreover, the white coating layer is not formed on the external surface of the combustion chamber due to the inflow of the air, as illustrated in FIG. 2A, but is formed on the internal surface of the combustion chamber like the outlet of the turbine, as illustrated in FIG. 4, which is a photograph taken by a endoscope

### Example 2

### SEM Analysis of a Coating Layer

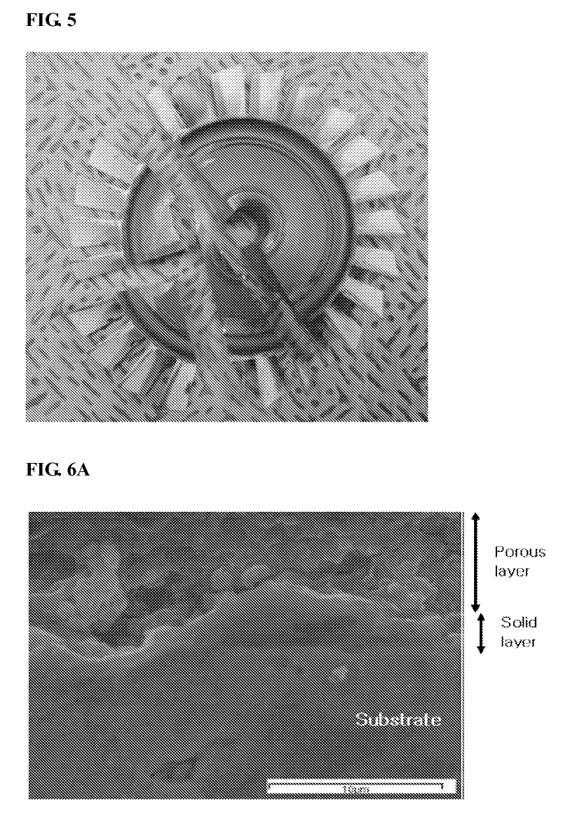

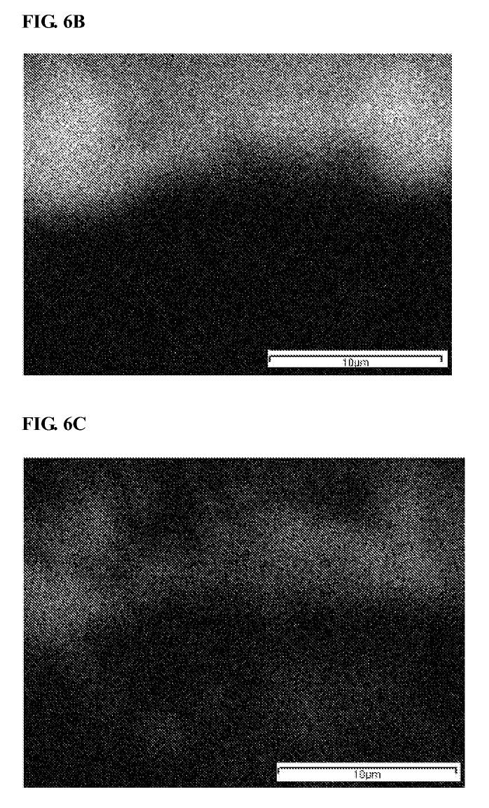

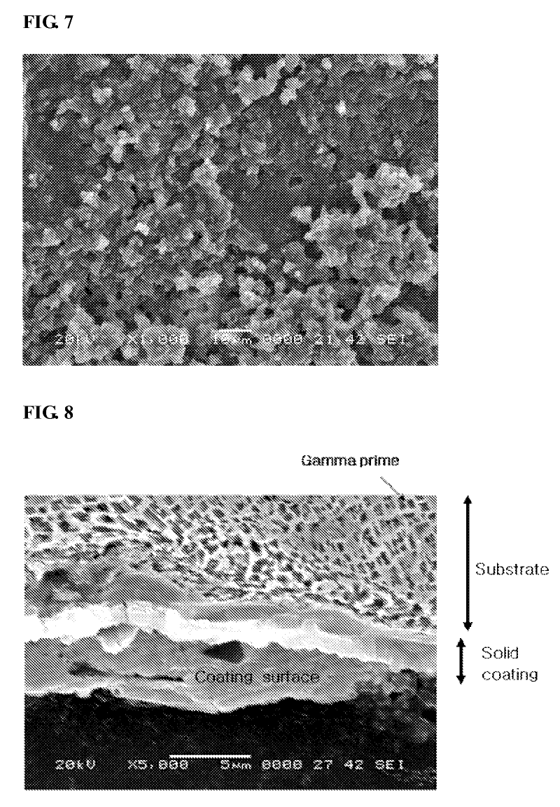

FIG. 5 is a photograph of the turbine blades, on which the coating layer of example 1 is formed. From FIG. 5, it is understood that the coating layer is uniformly formed on the surfaces of integral blades. In order to analyze the section of the coating layer, the turbine is cut, as shown in FIG. 5. The surface and the section of the coating layer are respectively analyzed using a scanning electron microscope (SEM) produced by JEOL Ltd. in Japan. FIG. 6A is a SEM image of the section of the coating layer formed on the turbine blades, and FIGS. 6B and 6C are component maps of silicon and oxygen of the coating layer of FIG. 6A. As shown in FIG. 6A, the coating layer includes a solid layer having a thickness of, e.g., 2 to 3 μm formed on a nickel-based alloy base material, and a porous layer having a thickness of 10 μm or more formed on the solid layer. From FIGS. 6B and 6C, it is understood that the coating layer is made of silicon oxide. The porous layer is not removed from the base material even by the rotation of the turbine blades at a high speed of 25,000 rpm or more and contained air, and thus serves as a thermal barrier coating layer for preventing high-temperature combustion gas (flame) from being directly transferred to a base metal, thereby being expected to improve the thermal resistance of components of the gas turbine. FIG. 7 is a SEM image of the external surface of the coating layer, substantially showing the porous layer. This porous layer is easily washed out with water of a high pressure, and thus only the solid layer remains on the base material, as shown in FIG. 8. In order to clearly show the coated portions, FIG. 8 shows precipitate having a rectangular shape, called gamma prime, by etching the base material.

As apparent from the above description, when a small amount of an organic compound including a metal ingredient is added to a fuel for a gas turbine, the organic compound burns together with the fuel, thus producing a solid metal oxide. The oxide uniformly coats all high-temperature components of the gas turbine, which contact combustion air during the operation of the gas turbine. That is, a method is provided for effectively depositing an anti-corrosion and anti-oxidation material, such as silicon dioxide, on the high-temperature components of the gas turbine, including blades rotating at a high speed during the operation of the gas turbine, without additional process, equipment and man power for coating the components, thus being economical.

Further, since the metal organic compound added to the fuel is easily controlled, the thickness and shape of the metal oxide produced by combustion are adjustable. Even when the coating layer is peeled off from a base material during use of the gas turbine, it is possible to form a new coating layer without stoppage of the operation of the gas turbine. Thus, the method is convenient.

Moreover, even in the case of the high-temperature components of the gas turbine, which are coated by thermal barrier coating (TBC) with Yttria Stabilized Zirconia (YSZ), the oxide, such as silicon dioxide, prevents oxygen from permeating into the base material through a YSZ layer, and thus prevents the YSZ layer from being peeled off from the base material due to the oxidation of the metal surface of the base material. Consequently, the method may elongate life spans of the high-temperature components.

Although an example embodiment of the present invention has been disclosed for illustrative purposes, those skilled in the art will appreciate that various modifications, additions and substitutions are possible, without departing from the scope and spirit hereof.

What is claimed is:

1. A method for forming an anti-corrosion and anti-oxidation coating layer on high-temperature components of a gas turbine using a fuel additive, comprising:
coating surfaces of the high-temperature components contacting combustion gas with a metal oxide having high thermal resistance during operation of the gas turbine by at least one of (a) adding a metal organic compound, including a metal ingredient, in one of (a) a gas and (b) a liquid state to a fuel of the gas turbine and (b) spraying the organic compound into combustion air so that the organic compound burns together with the fuel during the operation of the gas turbine to increase the thermal resistance of the high-temperature components.

2. The method according to claim 1, wherein the metal organic compound includes a silicon organic compound.

3. The method according to claim 1, wherein the high-temperature components of the gas turbine include at least one of (a) a combustion can, (b) first-stage blades, (c) first-stage nozzles, (d) second-stage blades and (e) and second-stage nozzles.

4. The method according to claim 1, wherein the high-temperature components of the gas turbine are coated in the coating step by thermal barrier coating (TBC) with Yttria Stabilized Zirconia (YSZ).

5. The method according to claim 1, wherein the fuel of the gas turbine includes at least one of (a) LNG, (b) diesel and (c) kerosene fuel.

6. The method according to claim 1, wherein an amount of the metal organic compound added is in a range of 3% or less.

7. The method according to claim 1, wherein the metal oxide formed on the high-temperature components includes silicon dioxide.

8. The method according to claim 7, wherein the metal oxide formed on the high-temperature components has a thickness of 1 to 10 μm.

9. The method according to claim 2, wherein the silicon organic compound includes tetraethyl orthosilicate (TEOS).

10. The method according to claim 2, wherein the silicon organic compound includes silicon oil.
